(19) United States
(12) Patent Application Publication
(10) Pub. No.: US 2016/0284491 A1
(43) Pub. Date: Sep. 29, 2016

(54) FLEXIBLE CIRCUIT BOARD FOR KEYBOARD

(71) Applicant: Jiangsu Transimage Technology Co., Ltd, Yangzhou City (CN)

(72) Inventor: Weimin Zou, Yangzhou City (CN)

(21) Appl. No.: 15/004,517

(22) Filed: Jan. 22, 2016

(30) Foreign Application Priority Data
Mar. 24, 2015 (CN) 2015201662485

(51) Int. Cl. H01H 13/702; H05K 1/14; H05K 1/02

(52) U.S. Cl. CPC H01H 13/702; H05K 1/028; H05K 1/144

(57) ABSTRACT

A flexible circuit board for keyboard, including an upper layer polyester film, a spacer and a lower layer polyester film, wherein the upper layer polyester film, the spacer and the lower layer polyester film are overlapped in order, the lower surface of the upper layer polyester film is provided with a first printed circuit, the upper surface of the lower layer polyester film is provided with a second printed circuit, the spacer is provided with a third printed circuit, the third printed circuit is provided with a connecting point, and the connecting point contacts and is communicated with the first printed circuit.

### TECHNICAL FIELD

The invention relates to an input device using a manually operating switch, and more particular to a flexible circuit board for keyboard, which is applied in a laptop keyboard.

### BACKGROUND

In prior art, the laptop keyboard generally adopts the flexible circuit board as a switch, such as a polyester film switch, which has an upper-middle-lower-layer structure, the upper layer polyester film and the lower layer polyester film are printed with silver wires and spaced by the middle layer, and the middle layer is opened with a spacer hole in the position of the contact point between the upper layer and the lower layer. When pressing the key, the communication of the key is achieved by means of the deformation in the pressing place and the contact of the contact point. Some printed silver wires do not have enough routing space with the limit of the design size of the keyboard, and can only be distributed in the mode of UV and jumper wire, thereby resulting in more printing processes on the upper layer polyester film and the lower layer polyester film at present. As a result, the production cost is higher and the process yield is lower. Designing a flexible circuit board for keyboard capable of simplifying the printing process has become an urgent technical problem.

### SUMMARY

Invention object: in order to overcome the shortage in the prior art, the invention provides a flexible circuit board for keyboard with simple technology.

Technical scheme: in order to solve the above technical problem, a flexible circuit board for keyboard provided according to the invention includes an upper layer polyester film, a spacer and a lower layer polyester film, wherein the upper layer polyester film, the spacer and the lower layer polyester film are overlapped in order, the lower surface of the upper layer polyester film is provided with a first printed circuit, the upper surface of the lower layer polyester film is provided with a second printed circuit, the spacer is provided with a third printed circuit, the third printed circuit is provided with a connecting point, and the connecting point contacts and is communicated with the first printed circuit.

Preferably, the spacer is provided with a fourth printed circuit and the fourth printed circuit is communicated with the second printed circuit through a contact point.

Preferably, the part of the third printed circuit except the connecting point is uniformly coated with an UV layer, and the part of the fourth printed circuit except the contact point is uniformly coated with an UV layer.

Beneficial effects: the invention adopts a brand-new design concept and fully utilizes the space of an thin-film switch, by printing the middle layer, so that the design routing is not limited by the keyboard mechanism any more, without connecting the circuit via redundant processes. In this way, the technological process is simplified, the badness of the production process is reduced, and the design and production cost is saved.

In addition to the above technical problems solved by the invention, the technical features forming the technical scheme and the advantages brought about by the technical features of the technical scheme, the other technical problems that can be solved by the flexible circuit board for keyboard according to the invention, the other technical features included in the technical scheme and the advantages brought about by these technical features will be further described for details with reference to the drawings.

### BRIEF DESCRIPTION OF THE DRAWINGS

FIG. 1 is a schematic structural diagram of an existing flexible circuit board for keyboard;

FIG. 2 is a schematic structural diagram of the flexible circuit board for keyboard according to the invention;

In figure: 1: upper layer polyester film, 2: spacer, 3: middle layer polyester film, 2-1: spacer hole, 4: first printed circuit, 5: second printed circuit, 6: third printed circuit, 7: fourth printed circuit, 8: upper layer routing, 9: lower layer routing

### DETAILED DESCRIPTION OF THE PREFERRED EMBODIMENTS

### Embodiments

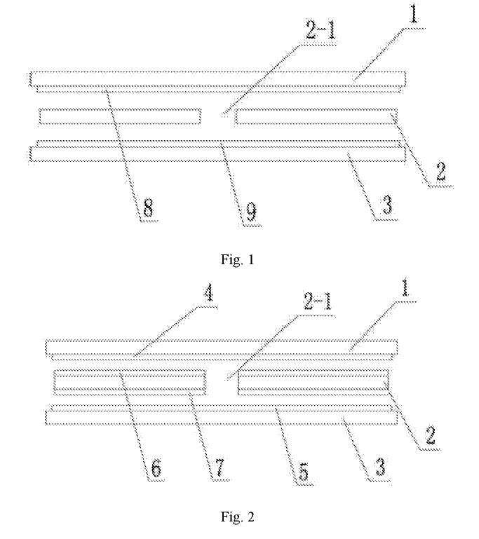

As shown in FIG. 1, the production process of the laptop keyboard polyester film switch is in a three-layer structure at present, including an upper layer polyester film 1, a spacer 2 and a lower layer polyester film 3. The lower surface of the upper layer polyester film 1 is provided with upper layer routing 8 including a printed silver wire, UV, a jumper wire and glue; the middle layer spacer 2 is emptied in the position of a key and is communicated by pressing; and the upper layer and the lower layer are blocked in other positions to prevent direct short circuit. The lower surface of the lower layer polyester film 3 is provided with lower layer routing 9 also including a printed silver wire, UV, a jumper wire and glue.

As shown in FIG. 2, the flexible circuit board provided according to the invention is also provided with an upper layer polyester film 1, a spacer 2 and a lower layer polyester film 3, wherein the upper layer polyester film 1, the spacer 2 and the lower layer polyester film 3 are overlapped in order, the lower surface of the upper layer polyester film 1 is provided with a first printed circuit 4, and the upper surface of the lower layer polyester film 3 is provided with a second printed circuit 5. The upper surface of the spacer 3 is provided with a third printed circuit 6, the third printed circuit 6 is provided with a connecting point and the connecting point contacts and is communicated with the first printed circuit 4. The lower surface of the spacer 3 is provided with a fourth printed circuit 7, the fourth printed circuit 7 is communicated with the second printed circuit 5 through a contact point. The middle layer printed circuit can enable the whole flexible circuit board for keyboard to route more wires in a smaller scope, without connecting the wires that fail to pass through via the jumper wire, so the process is reduced, the technological process is simplified, and the cost is saved.

From the above comparison, it can be noted that the current routing is limited by the keyboard mechanism, the single silver wire fails to pass through the circuit, and needs the jumper wire to connect; while the upper layer, the middle layer and the lower layer are printed circuits according to the invention, which fully utilizes the space of the film switch and simplifies the process.

The production process of the existing circuit board is as follows:

Upper layer: polyester film printed silver wire—printed carbon—printed UV1—printed UV2—printed jumper wire—printed glue;

Lower layer: polyester film printed silver wire-printed carbon—printed UV1—printed UV2—printed jumper wire—printed glue.

The production process of the invention is as follows:

Upper layer: polyester film printed silver wire—printed carbon—printed glue;

Lower layer: polyester film printed silver wire—printed glue;

Middle layer: polyester film printed silver wire.

It is thus clear that the printed UV1, UV2 and the jumper wire process of the upper layer and the lower layer are saved by adopting the structure according to the invention, so the design and production process is simplified, the badness in production is reduced, and the cost is saved.

The embodiments of the invention are described for details hereinabove with reference to the drawings, but the invention is not limited to the described embodiments. For those skilled in the art, various changes, modifications, replacement and transformation for these embodiments will still pertain to the scope of the claims of the invention within the scope of the principle and technical ideas of the invention.

1. A flexible circuit board for keyboard, comprising an upper layer polyester film, a spacer and a lower layer polyester film, wherein the upper layer polyester film, the spacer and the lower layer polyester film are overlapped in order, the lower surface of the upper layer polyester film is provided with a first printed circuit, the upper surface of the lower layer polyester film is provided with a second printed circuit, the spacer is provided with a third printed circuit, the third printed circuit is provided with a connecting point, and the connecting point contacts and is communicated with the first printed circuit.

2. The flexible circuit board for keyboard according to claim 1, wherein the spacer is provided with a fourth printed circuit and the fourth printed circuit is communicated with the second printed circuit through a contact point.

3. The flexible circuit board for keyboard according to claim 1, wherein the part of the third printed circuit except the connecting point is uniformly coated with an UV layer.

4. The flexible circuit board for keyboard according to claim 2, wherein the part of the fourth printed circuit except the contact point is uniformly coated with an UV layer.
